(19) United States
(12) Patent Application Publication
(10) Pub. No.: US 2007/0227575 A1
(43) Pub. Date: Oct. 4, 2007

(54) Thermopile element and infrared sensor by using the same

(75) Inventors: Yoshiki Kato, Tokyo (JP); Jun Kamiyama, Tokyo (JP)

Correspondence Address: REISING, ETHINGTON, BARNES, KISSELLE, P.C., P O BOX 4390, TROY, MI, 48099-4390, US

(73) Assignee: Ishizuka Electronics Corp.

(21) Appl. No.: 11/234,901

(22) Filed: Sep. 26, 2005

(30) Foreign Application Priority Data
Oct. 1, 2004 (JP) 2004-289696

(51) Int. Cl. H01L 35/28

(52) U.S. Cl. 136/224

(57) ABSTRACT

Providing a thermopile element which can follow securely a temperature change of a cold junction of a thermopile according to temperature change of environment, the thermopile element includes a membrane provided on a silicon substrate, a heat sink provided around the membrane, a thermopile structured with a plurality of hot junctions and a plurality of cold junctions arranged on the membrane and on the heat sink, and a thin film thermistor for detecting a temperature of the cold junction received and fixed in a recess formed on the heat sink of the thermopile element.

### REFERENCE TO RELATED APPLICATIONS

This application claims the benefit of Japanese Patent Application No. 2004-289696 filed on Oct. 1, 2004.

### BACKGROUND OF THE INVENTION

1. Field of the Invention

This invention relates to a structure of a thermopile element for measuring a temperature without contact, in detail, the thermopile element structured by that a heat-sensitive element is received and fixed in a recess formed on a heat sink, for detecting securely a temperature at a cold junction located on the heat sink, on which a thermopile structured with a hot junction and the cold junction is mounted, and an infrared sensor by using the thermopile element.

2. Description of the Related Art

Usually, a thermal type infrared detector is known as an example of an infrared detector for detecting a surface temperature of an object without contact.

The thermal type infrared detector is a sensor for detecting the surface temperature of a high temperature object or a moving object without contact. The thermal type infrared detector detects the surface temperature of the object to be detected by detecting a change of resistance value of a heat-sensitive resistor or a change of voltage value of a thermocouple, forming the infrared detector. The change is caused by temperature rising of the infrared detector by infrared energy radiated from the object to be detected. Since an infrared ray dose radiated from the object to be detected is very small, a heat-sensitive element of the detector is required to have a small heat capacity and a high infrared absorption. In a view point of manufacturing, high precise element producing technology is required. Therefore, the detector is usually formed by semiconductor fine machining process.

A thermopile provided at a thermopile type infrared sensor, disclosed by Japan Patent Laid Open H05-90646, includes a pit formed by removing a part of a substrate corresponding to a rear side of a silicone substrate by anisotropic etching and a membrane structure to support only at a surround area of an insulating film formed on the substrate. The thermopile has a structure where a hot junction of a thermocouple formed with different metals as an infrared detector is provided on the membrane and a cold junction of the thermocouple is provided on a heat sink around the membrane. Since a thermal resistance between the infrared detector and the heat sink is increased by structuring above, a heat capacity of the infrared detector can be reduced and an infrared detector with high speed response and high sensitivity can be given. In the thermopile structured above, a thin film thermistor for temperature compensation is arranged in the vicinity of the cold junction for measuring the temperature of the object to be measured securely. Physically, the thin film thermistor is formed to have an approximately 500 nm thick film on the heat sink of the substrate by spattering with a target of a thermistor material made of a metal oxide, and to be patterned as a thin film thermistor by photo-etching. After that, by providing a comb-shape thermistor electrode on the thin film thermistor, the thermopile type infrared sensor with the thin film thermistor for measuring the temperature of the cold junction is structured. Thus, the thin film thermistor is provided on the heat sink to measure securely a temperature change at the cold junction, so that the temperature of the object to be detected can be detected securely.

Instead of the structure of forming the thin film thermistor on the heat sink of the substrate as mentioned above, the structure of a thermopile device, in which a chip thermistor is mounted on the heat sink, is disclosed by Japan Patent Laid Open 2003-65854. The thermopile device is provided with a thin film member forming a diaphragm, a heat sink around the thin film member, a thermopile element riding on the thin film member and the heat sink and having a plurality of thermocouples formed to place each cold junction on the heat sink and chip thermistors mounted on each cold junction of the thermopile element. According to the above structure, the temperatures of the cold junction and the chip thermistor can follow a change of an environmental temperature quickly without a time lag, so that temperature measuring can be acted with high accuracy regardless of an environmental change.

### SUMMARY OF THE INVENTION

### Objects to be Solved

The thermopile type infrared sensor disclosed above is formed by patterning the thin film thermistor on the heat sink by spattering with the target of the thermistor material made of the metal oxide. After forming the metal oxide film of the thin film thermistor, a heat treatment of high temperature 400-900 degree C is required. After forming a protecting film such as a glass film on the formed thin film thermistor, a heat treatment is also required. Repeating heat treatment of high temperature causes thermal deformation of the membrane supporting the thermopile, cracking and breakage. Thereby, a defective product in complete thermopile products is increased so that a yield of the product goes down. At the present time, it is very difficult technically to form the thin film thermistor of the metal oxide on the substrate of the thermopile. Even if the thermopile is manufactured as a good one, when the thin film thermistor has a failure of characteristics, the complete product becomes defective so that the yield will be decreased largely.

According to the other thermopile device disclosed above, the chip thermistor is mounted on the heat sink of the thermopile element. Only one surface of the chip thermistor is touched with the heat sink, and the other surfaces of the chip thermistor are exposed to the environment. Thereby, the chip thermistor is affected by a change of environment, so that it is difficult to detect securely the temperature at the cold junction of the heat sink. Since only one surface of the chip thermistor touches to the heat sink, thermal response against a change of the temperature of the heat sink is too slow to detect the change of the temperature at the cold junction quickly.

Objects of the present invention are to show a structure of a thermopile element, in which a heat sensitive element for overcoming the above problem and to provide a high sensitive thermopile element.

### How to Attain the Object of the Present Invention

In order to attain the object of the present invention, a thermopile element includes a substrate, a membrane provided on the substrate, a heat sink provided around the membrane, a thermopile structured with a plurality of hot junctions and a plurality of cold junctions arranged on the membrane and on the heat sink, and a heat-sensitive element received and fixed in a recess formed on the heat sink where the cold junction is arranged.

The thermopile element according to an aspect of the present invention is characterized in the thermopile as mentioned above in that one of a thin-film thermistor and a chip-type thermistor is used as the heat-sensitive element.

An infrared sensor by using the thermopile as mentioned above includes a stem, on which the thermopile is mounted, pin terminals provided at the stem and connected respectively to an output terminal of the thermopile structuring the thermopile element and to a lead pad connected to the heat-sensitive element, and a cap provided with a window, a material of which can transmit an infrared ray selectively, and the stem and the cap are sealed together.

### EFFECTS OF THE INVENTION

In the thermopile according to the present invention, includes the substrate, the membrane provided at the substrate, the heat sink provided around the membrane, the thermopile structured with the plurality of hot junctions and the plurality of cold junctions arranged on the membrane and on the heat sink, and the heat-sensitive element received and fixed in the recess formed on the heat sink where the cold junction is arranged. Thereby, five surfaces of the heat-sensitive element with a rectangular solid shape are placed in the recess so that a temperature change of the heat sink can be detected securely and rapidly so as to measure the temperature with high accuracy. Especially, when a thin film thermistor is applied as the heat-sensitive element, the small thin film thermistor with a small heat capacity can rapidly detect the temperature of the heat sink through the substrate in the recess and the temperature can be measured with high accuracy. After inspecting the characteristics of the heat-sensitive element, good products can be selected for application so that a yield of the infrared sensor assembled as complete products can be improved.

The above and other objects and features of this invention will become more apparent from the following description taken in conjunction with the accompanying drawings.

### BRIEF DESCRIPTION OF THE DRAWINGS

FIG. 1 is a partially sectional perspective view showing a structure of a thermopile element according to the present invention;

FIG. 2A is a cross-sectional view taken along the line 2A-2A in FIG. 1;

FIG. 3 is an exploded perspective view of an infrared sensor by using the thermopile element according to the present invention; and

FIG. 4 is a graph of curves showing measured heat responses of the thermopile element of the present invention and a thermopile by prior art.

### DESCRIPTION OF THE PREFERRED EMBODIMENT

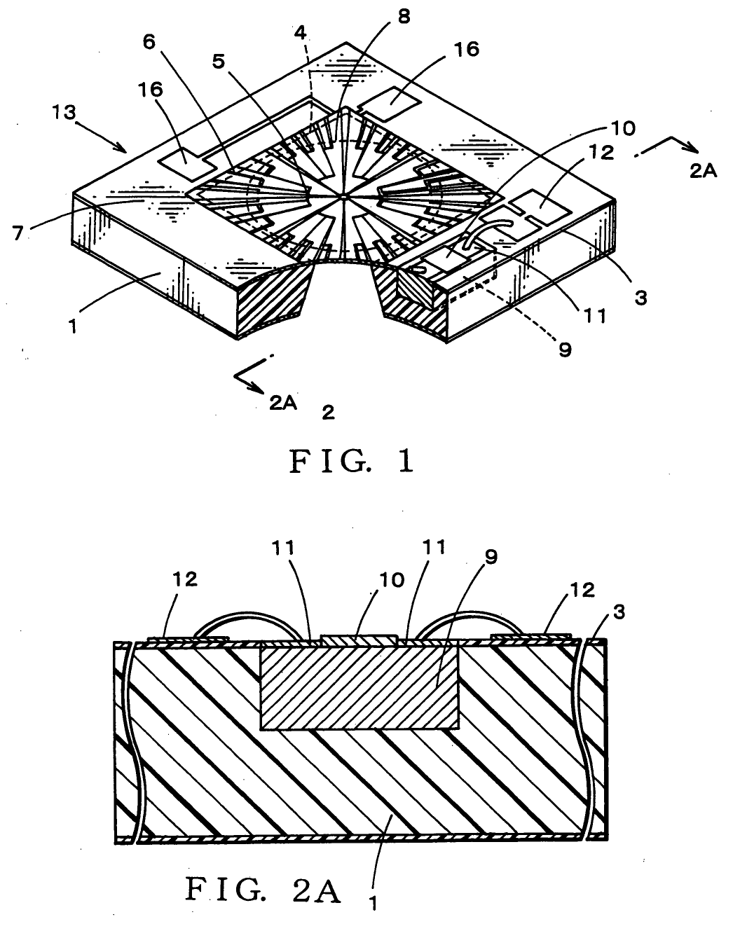

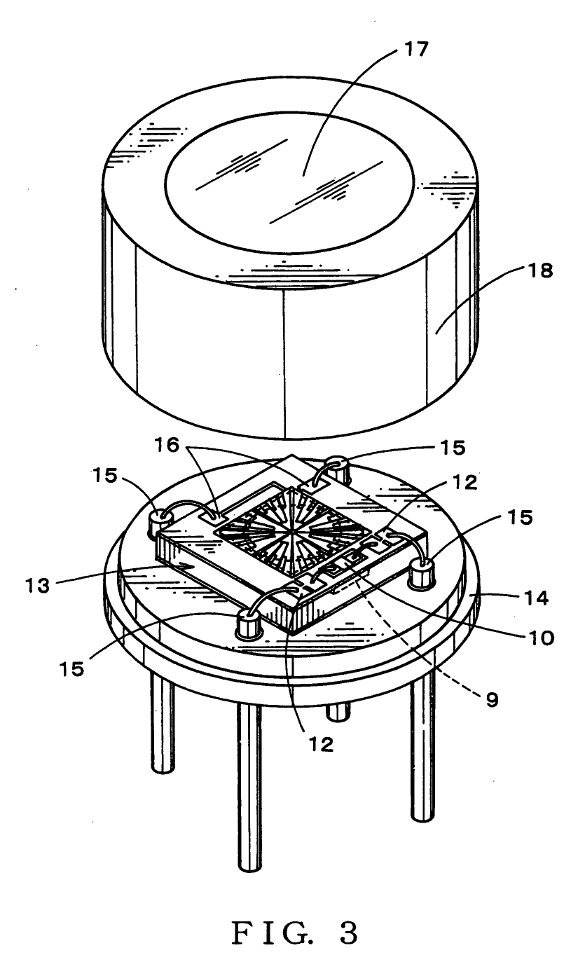

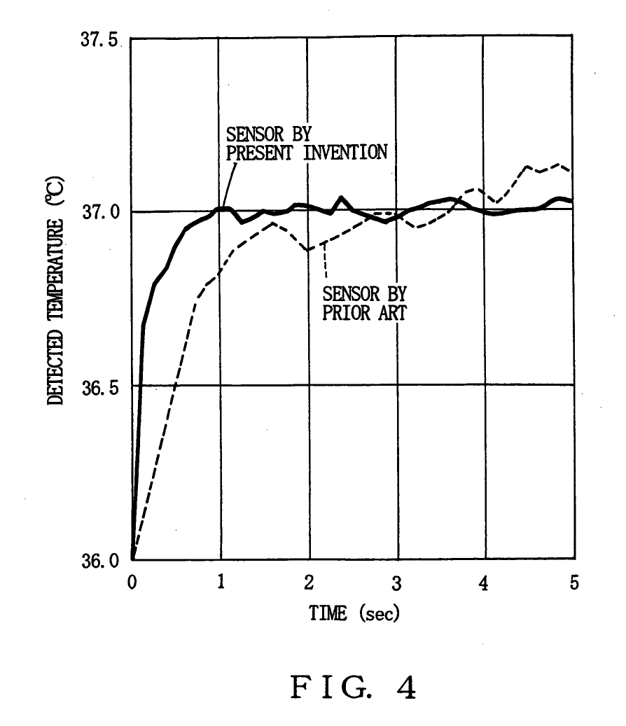

An embodiment according to the present invention is described with reference to Figures. FIG. 1 is a partially sectional perspective view showing a structure of a thermopile element according to the present invention. FIG. 2A is a cross-sectional view taken along the line 2A-2A in FIG. 1. FIG. 3 is an exploded perspective view of an infrared sensor by using the thermopile element according to the present invention. FIG. 4 is a graph of curves showing measured heat responses of the thermopile element of the present invention and a thermopile by prior art.

In FIGS. 1 and 2A, an insulating film 3 made of for example silicon dioxide or silicon nitride is provided on one surface of a silicon substrate 1, and a pit 2 is formed from a rear surface of the silicon substrate 1 by anisotropic etching. A membrane 4 having the insulating film 3 is formed at a top of the pit 2. A hot junction 5 of a thermocouple made of different metals is provided on the membrane 4, and a cold junction 6 of the thermocouple is provided at a heat sink 7 around the membrane 4. A plurality of such thermocouples connected in series forms a thermopile. An infrared-ray absorber 8 such as a blackbody is provided at the hot junction 5 of the thermopile. A recess 9, which can receive a heat-sensitive element 10 for example a thin film thermistor element, is formed at the heat sink 7. After the heat-sensitive element 10 is received and fixed in the recess 9, an electrode 11 of the heat-sensitive element 10 and a lead pad 12 provided at the heat sink 7 are connected by a connecting method, for example wire-bonding. In this embodiment, a thin film thermistor element is applied for the heat-sensitive element 10. The applied thin film thermistor element has a length of 0.4 mm, a width of 0.1 mm and a thickness of 0.05 mm. A thin film of the thermistor is formed by spattering with a target of metal oxide. A thermopile element 13 structured as mentioned above is mounted and fixed at a central position of a stem 14 as shown in FIG. 3. An output terminal 16 of the thermopile 13 and the lead pad 12 wire-bonded with the electrode of the thin film thermistor element are connected with each pin terminal 15 provided at the stem 14. By welding a cap 18 having a window 17, a material of which can transmit the infrared ray selectively, and the stem 14 for sealing, an infrared sensor is completed. In the other embodiment, a membrane can be formed by adhering an insulating film, in which a thermopile is formed, on an insulating substrate such as an aluminum oxide in which a pit is formed previously. By forming a recess to receive a heat-sensitive element at a heat sink around the membrane and placing and fixing the heat-sensitive element in the recess, and by connecting an electrode of the heat-sensitive element and a lead pad provided at the heat sink by wire-bonding, a thermopile element can be assembled. Instead of the thin film thermistor as the applied heat-sensitive element shown in the embodiment, a bulk-type or multilayer-type chip thermistor or thick film thermistor can be applied.

In the complete infrared sensor, a temperature of the membrane is increased by receiving the infrared ray radiated from the object to be detected by the infrared absorber of the thermopile element, and temperature difference between the hot junction and the cold junction of the thermopile element occurs. Electromotive power generated by the temperature difference is outputted from the output terminal of the thermopile element as an output voltage of the thermopile element. Simultaneously, a change of the temperature of the cold junction can be rapidly detected as a change of resistance by the thin film thermistor element received and fixed in the recess formed at the heat sink of the substrate. Thereby, the incident infrared ray dose can be detected securely so that the temperature of the object to be detected can be measured securely.

FIG. 4 is a graph of curves showing measured heat responses of the thermopile element, which the thin film thermistor element for temperature compensation is mounted in the recess provided at heat sink, according to the present invention and a thermopile element, which the thin film thermistor element is formed on the heat sink, by prior art, with a blackbody chamber which temperature is controlled at 37 degree C.

As shown in the graph of measured results, 3 seconds is required to reach the temperature of 37 degree C at the thermopile element by prior art, and the temperature after reaching 37 degree C is increasing over the temperature of 37 degree C. Thus, a long time is required to stabilize the measured temperature. 1.0 seconds is required to reach the temperature of 37 degree C at the thermopile element according to the present invention, and the temperature after reaching 37 degree C is stable. As shown in the result, the thermopile element of the present invention can detect a temperature change of the heat sink securely and rapidly, so that the temperature can be measured with high accuracy.

Although the present invention has been fully described by way of examples with reference to the accompanying drawings, it is to be noted that various change and modifications can be made with the scope of the present invention as defined by the following claims.

What is claimed is:

1. A thermopile element comprising:
a substrate;
a membrane provided on the substrate;
a heat sink provided around the membrane;
a thermopile structured with a plurality of hot junctions and a plurality of cold junctions arranged on the membrane and on the heat sink; and
a heat-sensitive element received and fixed in a recess formed on the heat sink where the cold junction is arranged.

2. The thermopile element according to claim 1, wherein one of a thin-film thermistor and a chip-type thermistor is used as the heat-sensitive element.

3. An infrared sensor by using the thermopile as claimed in claim 1 or 2, comprising:
a stem, on which said thermopile is mounted;
pin terminals provided at the stem and connected respectively to an output terminal of the thermopile structuring the thermopile element and to a lead pad connected to the heat-sensitive element; and
a cap provided with a window, a material of which can transmit an infrared ray selectively,
wherein the stem and the cap are sealed together.
